(19) United States
(12) Patent Application Publication
(10) Pub. No.: US 2013/0240820 A1
(43) Pub. Date: Sep. 19, 2013

(54) PHASE CHANGE RANDOM ACCESS MEMORY AND FABRICATION METHOD OF HEATING ELECTRODE FOR THE SAME

(71) Applicant: SK HYNIX INC., Gyeonggi-do (KR)

(72) Inventors: Hee Seung SHIN, Gyeonggi-do (KR); Ky Hyun HAN, Gyeonggi-do (KR)

(73) Assignee: SK hynix Inc., Gyeonggi-do (KR)

(21) Appl. No.: 13/871,577

(22) Filed: Apr. 26, 2013

Related U.S. Application Data
(63) Continuation-in-part of application No. 12/975,976, filed on Dec. 22, 2010.

(30) Foreign Application Priority Data
Jul. 30, 2010 (KR) 10-2010-0074017

(51) Int. Cl. H01L 45/00

(52) U.S. Cl. CPC H01L 45/126
USPC 257/3; 438/381

(57) ABSTRACT

A method for fabricating a PCRAM includes forming a switching element on a semiconductor substrate, forming an interlayer dielectric layer of a multilayer-structure by sequentially stacking a plurality of material layers having different etching properties on the semiconductor substrate having the switching element formed thereon, and by patterning the plurality of material layers to have different lengths or different side shapes, forming a heating electrode on sidewalls of the interlayer dielectric layer and an upper surface of the switching element, and forming a phase change material layer to fill a space inside of the heating electrode.

### CROSS-REFERENCES TO RELATED APPLICATION

The application is a continuation-in-part of application Ser. No. 12/975,976, filed Dec. 22, 2010, titled “Phase Change Random Access Memory and Method for Fabricating the Same”, which is incorporated here in by reference in its entirety as if set forth in full.

### BACKGROUND

1. Technical Field

The present invention relates to a nonvolatile memory apparatus, and more particularly, to a phase change random access memory (PCRAM) and a fabrication method of heating electrode for the same.

2. Related Art

A PCRAM causes a phase change of a phase change material by applying joules of heat to the phase change material through a heating electrode serving as a heater. Accordingly, the PCRAM records/erases data by using an electrical resistance difference between a crystalline state and amorphous state of the phase change material.

As such, the PCRAM may transfer heat to the phase change material through the heating electrode or release the applied heat from the phase change material to the outside. In order to increase a driving speed, the heat releasing speed should be increased.

### SUMMARY

A PCRAM having an increased driving speed and a method for fabricating of heating electrode for the same are described herein.

In one exemplary embodiment of the present invention, a fabrication method of a heating electrode includes of: forming a bottom structure having a switching element on a semiconductor substrate; forming an interlayer dielectric layer of a multilayer-structure by sequentially stacking a plurality of material layers having different etching properties on the semiconductor substrate having the bottom structure formed thereon, and by patterning the plurality of material layers to have different lengths or different side shapes; and forming a heating electrode on sidewalls of the interlayer dielectric layer and an upper surface of the bottom structure, wherein at least one of the interlayer dielectric layer of the multilayer-structure comprises a heat sink layer.

In another exemplary embodiment of the present invention, a PCRAM includes: a bottom structure including a plurality of switching elements formed on a semiconductor substrate; an interlayer dielectric layer of a multilayer-structure formed on the semiconductor substrate, exposing the bottom structure, and having a raised and grooved side surface; and a heating electrode formed on sidewalls of the interlayer dielectric layer and an upper surface of the bottom structure, wherein at least one of the interlayer dielectric layer of the multilayer-structure comprises a heat sink layer.

### BRIEF DESCRIPTION OF THE DRAWINGS

Features, aspects, and embodiments of the present invention will be more clearly understood from the following detailed description and the accompanying drawings, in which:

FIGS. 1 to 7 are cross-sectional views illustrating a method for fabricating a PCRAM according to one exemplary embodiment of the present invention; and

FIG. 8 is a cross-sectional view illustrating a method for fabricating a PCRAM according to another exemplary embodiment of the present invention.

### DETAILED DESCRIPTION

Hereinafter, a PCRAM and a method for fabricating the same according to the present invention will be described below with reference to the accompanying drawings through exemplary embodiments.

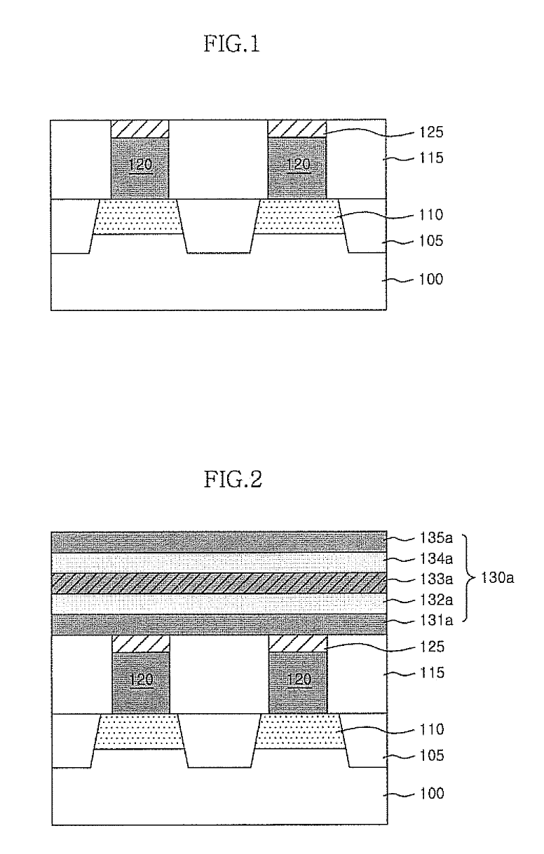

FIGS. 1 to 7 are cross-sectional views illustrating a method for fabricating a PCRAM according to one exemplary embodiment of the present invention.

Referring to FIG. 1, an isolation layer 105 is formed in desired portions of a semiconductor substrate 100, thereby defining a plurality of active areas. A method of forming the isolation layer (e.g., an STI process) is known in the art and omitted for the description purpose. Impurities are implanted into the respective active areas at a desired depth, thereby forming junction-area-shaped word lines (hereinafter, referred to as junction word lines) 110.

A first interlayer dielectric layer 115 is formed by depositing a first interlayer material on the semiconductor substrate 100 having the junction word lines 110 formed therein. Then, the first interlayer dielectric layer 115 is etched to expose a desired portion of each junction word line 110, thereby forming a diode contact hole (not illustrated).

At this time, the diode contact hole may be positioned in the vicinity of an intersection point between the junction word line 110 and a bit line to be subsequently formed. A diode 120 serving as a switching element is formed in the diode contact hole. In this exemplary embodiment, the diode 120 may include a PN diode.

The PN diode 120 may be formed by the following process: an n-type selective epitaxial growth (SEG) layer is formed in the diode contact hole, and p-type impurities are implanted onto the n-type SEG layer to form the PN diode 120.

When a metal word line (not illustrated) is interposed between the diode 120 and the junction word line 110 in consideration of the resistance of the junction word line 110, the diode 120 may be implemented as a Schottky diode formed of a polysilicon layer.

A transition metal layer (not illustrated) is deposited on the resultant substrate structure having the diode 120 formed therein, and a heat treatment is performed on the resultant substrate structure to selectively form an ohmic contact layer 125 on the diode 120. Then, the remaining transition metal layer is removed.

Referring to FIGS. 2 and 3, a plurality of material layers 130a having different etching properties are sequentially deposited on the resultant substrate structure 100 having the ohmic contact layer 125 formed therein, and then patterned to form an interlayer dielectric pattern 130b having heating electrode contact holes 121 and 122 which expose the ohmic contact layer 125. The interlayer dielectric pattern 130b has a multilayer structure.

More specifically, first to fifth material layers 131a to 135a are sequentially deposited on the resultant substrate structure having the ohmic contact layer 125 formed therein. Then, the multilayer-structure interlayer dielectric pattern 130b, having the heating electrode contact holes 121 and 122 which expose the upper surface of the ohmic contact layer 125, is formed by a first etching process in which a wet etching method using CF₄ solution or CHF₃ solution or a dry etching method is applied.

At this time, the first and fifth material layers 131a and 135a of FIG. 2 are material layers for forming first and fifth dielectric patterns 131b and 135b, respectively, formed at the lowermost and uppermost parts of the interlayer dielectric pattern 130b of FIG. 3. The first and fifth dielectric patterns 131b and 135b may be formed of silicon nitride.

The second and fourth material layers 132a and 134a of FIG. 2 are material layers for forming second and fourth dielectric patterns 132b and 134b, respectively, formed between the first and fifth dielectric patterns 131b and 135b of FIG. 3. The second and fourth dielectric patterns 131b and 135b may be formed of silicon oxide or silicon oxynitride.

The third material layer 133a of FIG. 2 is a material layer for forming a third dielectric pattern 133b formed between the second and fourth dielectric patterns 132b and 134b of FIG. 3. The third material layer 133a may be formed as a heat sink layer for releasing the heat generated from the heating electrode. That is, the third dielectric pattern 133b may be formed of any material selected from a group consisting of a metal layer such as W, Ti, Mo, Ta, and Pt, a metal nitride layer such as TiN, TaN, WN, MoN, NbN, TiSiN, TiAlN, TiBN, ZrSiN, WSiN, WBN, ZrAlN, MoSiN, MoAlN, TaSiN, and TaAlN, a is silicide layer such as TiSi and TaSi, an alloy layer such as TiW, and a metal oxide (nitride) layer such as TiON, TiAlON, WON, TaON, and IrO₂, in order to increase the thermal conductivity of a heating electrode 140 to be subsequently formed.

In this exemplary embodiment, the material layers having different properties are alternately deposited to have a raised and grooved side surface. The positions of the first to fifth material layers 131a to 135a are not limited to the structure illustrated in FIGS. 2 and 3, and may be changed in other exemplary embodiments.

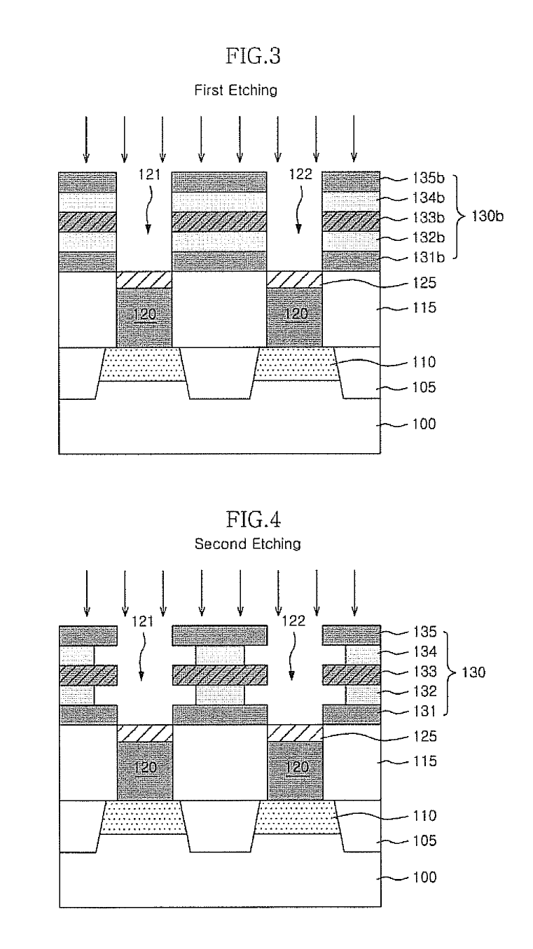

Referring to FIG. 4, a second etching process is performed on the resultant substrate structure having the multilayer-structure interlayer dielectric pattern 130b, thereby forming a second interlayer dielectric layer 130 of a multilayer-structure having a raised and grooved side surface.

More specifically, the second etching process, in which a dry etching method or a wet etching method using any one of a HF solution, buffered oxide etch (BOE), and a mixture of SiO₂ and SiN₂ is applied, is performed on the resultant substrate structure having the interlayer dielectric pattern 130b, thereby removing/etching portions of the second and fourth dielectric patterns 132b and 134b. Accordingly, second and fourth dielectric layers 132 and 134 may be formed to have a smaller length than first, third, and fifth dielectric layers 131, 133, and 135. At this time, the second and fourth dielectric layers 132 and 134 may be formed of silicon oxide such that they can be etched to have a different length from the other dielectric layers.

However, the second interlayer dielectric layer 130 according to this exemplary embodiment is not limited to the structure of FIG. 4. Referring to FIG. 9, the second interlayer dielectric layer 130 may be formed in such a manner that the dielectric layers 131, 133, 135, 136, and 137 of the respective layers have different shapes. Similar to the second interlayer dielectric layer 130 of FIG. 4, the second interlayer dielectric layer 130 of FIG. 9 may be formed by performing the second etching process, in which a dry etching method or a wet etching method using any one etching material of a HF solution, BOE, and a mixture of SiO₂ and SiN₂ is applied, on the resultant substrate structure having the interlayer dielectric pattern 130b formed therein. In this case, the second interlayer dielectric layer 130 of FIG. 9 may be formed in such a manner that side surfaces of the second and fourth dielectric layers 136 and 137 are curved/rounded. At this time, the second and fourth dielectric layers 136 and 137 may be formed of silicon oxynitride so as to have a curved/rounded shape as described above.

Where the second interlayer dielectric layer 130 of the multilayer-structure is formed in the above-described manners, a contact area between the second interlayer dielectric layer 130 and a heating electrode to be subsequently formed may be increased. As the surface area of the heating electrode is increased, the transmission speed of heat may be increased. As a result, the driving speed of the memory may be increased.

Moreover, heat generated from the heating electrode can easily be released by the third material layer 133a to be heat sink layer.

Referring to FIG. 5, the heating-electrode contact holes 121 and 122 of the resultant substrate structure having the second interlayer dielectric layer 130 of the multilayer-structure formed therein are filled with one or more conductive materials consisting of a metal layer such as W, Ti, Mo, Ta, and Pt, a metal nitride layer such as TiN, TaN, WN, MoN, NbN, TiSiN, TiAlN, TiBN, ZrSiN, WSiN, WBN, ZrAlN, MoAlN, MoAlN, TaSiN, and TaAlN, a silicide layer such as TiSi and TaSi, an alloy layer such as TiW, and a metal oxide (nitride) layer such as TiON, TiAlON, WON, TaON, and IrO₂.

The conductive material filling the heating electrode contact holes 121 and 122 is etched through an etch back process to remain on the sidewalls of the second interlayer dielectric layer 130 and the bottom of the heating electrode contact holes 121 and 122, thereby forming the heating electrode 140.

At this time, a chemical vapor deposition (CVD) method or a deposition method using TiCl₄ may be used to deposit the conductive material for forming the heating electrode 140. In this case, the to conductive material may be smoothly grown on the side walls of the second interlayer dielectric layer 130 having a raised and grooved side surface.

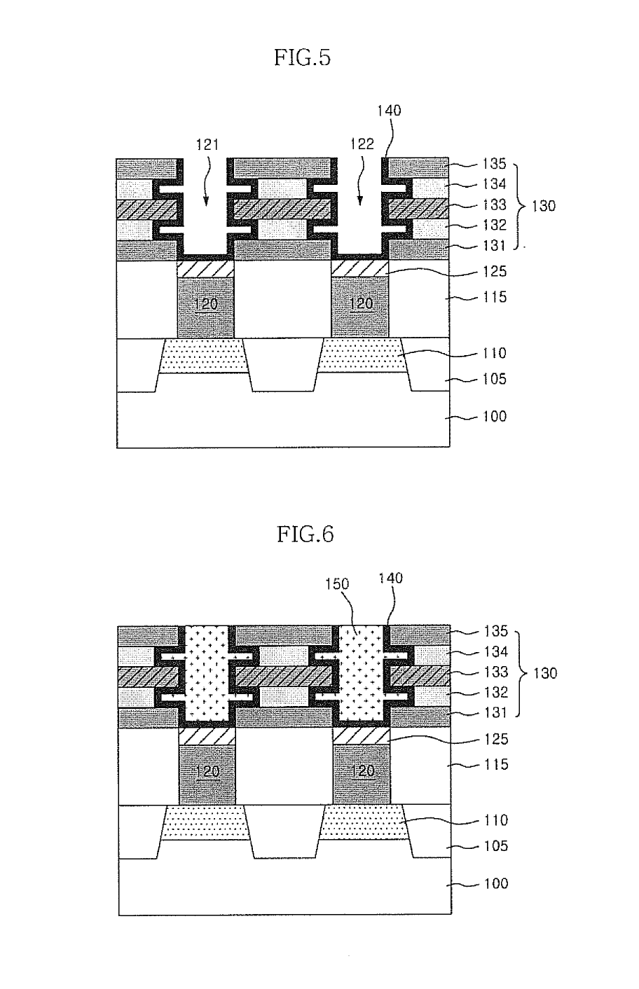

Referring to FIG. 6, a phase change material layer 150 is buried in the heating electrode contact holes 121 and 122 surrounded is by the heating electrode.

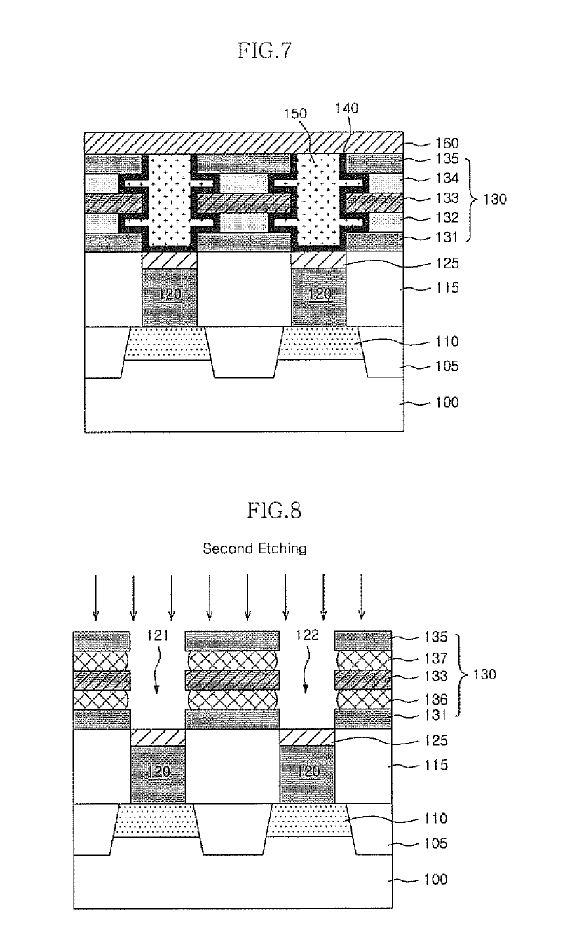

Referring to FIG. 7, a conductive layer (not illustrated) is deposited on the resultant substrate structure having the phase change material layer 150 formed therein, and patterned in a direction crossing the junction word line 110 to from an upper electrode 160.

At this time, the upper electrode 160 may be formed of Ti or TiN so as to be electrically coupled to the phase change material layer 150.

While the present invention has been described with respect to the specific embodiments, it will be apparent to those skilled in the art that various changes and modifications may be made without departing from the spirit and scope of the invention as defined in the following claims.

What is claimed is:

1. A fabrication method of a heating electrode for a phase change random access memory (PCRAM), comprising:
forming a bottom structure having a switching element on a semiconductor substrate;
forming an interlayer dielectric layer of a multilayer-structure by sequentially stacking a plurality of material layers having different etching properties on the semiconductor substrate having the bottom structure formed thereon, and by patterning the plurality of material layers to have different lengths or different side shapes; and
forming a heating electrode on sidewalls of the interlayer dielectric layer and an upper surface of the bottom structure,
wherein at least one of the interlayer dielectric layer of the multilayer-structure comprises a heat sink layer.

2. The method according to claim 1, wherein the forming of the interlayer dielectric layer comprises:
alternately depositing the plurality of material layers on the semiconductor substrate having the bottom structure formed thereon;
forming a plurality of interlayer dielectric patterns having a heating electrode contact hole exposing the bottom structure by performing a first etching process on the plurality of material layers; and
performing a second etching process to form the interlayer dielectric layer such that the heating electrode contact hole has a raised and grooved side surface.

3. The method according to claim 1, wherein the forming of the heating electrode is performed by using a chemical vapor deposition (CVD) method or a deposition method using a TiCl₄ solution.

4. The method according to claim 1, wherein the heat sink layer comprises W, Ti, or a Ti-based metal material.

5. The method according to claim 1, wherein at least one of the interlayer dielectric layer of the multilayer-structure comprises silicon nitride.

6. The method according to claim 5, wherein at least one of the interlayer dielectric layer of the multilayer-structure comprises silicon oxide.

7. The method according to claim 5, wherein at least one of the interlayer dielectric layer of the multilayer-structure comprises silicon oxynitride.

8. The method according to claim 2, wherein, a CF₄ solution or CHF₃ solution is used to perform the first etching process.

9. The method according to claim 8, wherein, any one of a HF solution, buffered oxide etch (BOE), and a mixture of SiO₂ and SiN₂ is used to perform the second etching process.

10. The method according to claim 1, further comprising:
forming a phase change material layer to fill an inside of the heating electrode.

11. The method according to claim 10, further comprising:
forming a bit line on the entire surface of the resultant structure having the phase change material layer formed therein.

12. A PCRAM comprising:
a bottom structure including a plurality of switching elements formed on a semiconductor substrate;
an interlayer dielectric layer of a multilayer-structure formed on the semiconductor substrate, exposing the bottom structure, and having a raised and grooved side surface; and
a heating electrode formed on sidewalls of the interlayer dielectric layer and an upper surface of the bottom structure,
wherein at least one of the interlayer dielectric layer of the multilayer-structure comprises a heat sink layer.

13. The PCRAM according to claim 12, wherein the interlayer dielectric layer comprises:
first and fifth interlayer dielectric patterns formed on the uppermost and lowermost parts of the interlayer dielectric layer, respectively;
second and fourth interlayer dielectric patterns formed between the first and fifth interlayer dielectric patterns; and
a third interlayer dielectric pattern formed between the second and fourth interlayer dielectric patterns.

14. The PCRAM according to claim 13, wherein the first, third, and fifth interlayer dielectric patterns are formed to have the same length.

15. The PCRAM according to claim 14, wherein the second and fourth interlayer dielectric patterns have a smaller length than the first, third, and fifth interlayer dielectric patterns.

16. The PCRAM according to claim 13, wherein the second and fourth interlayer dielectric patterns have a different side shape from the first, third, and fifth interlayer dielectric patterns.

17. The PCRAM according to claim 13, wherein the third interlayer dielectric pattern is the heat sink layer.

18. The PCRAM according to claim 12, further comprising:
a phase change material layer formed to fill an inside of the heating electrode.

19. The PCRAM according to claim 18, further comprising:
a bit line formed over the semiconductor substrate having the phase change material layer formed therein.
